(19) United States
(12) Patent Application Publication
(10) Pub. No.: US 2024/0413607 A1
(43) Pub. Date: Dec. 12, 2024

(54) KINK-FREE HIGH FILL-FACTOR BROAD AREA SEMICONDUCTOR LASER ON AN OFF-CUT SUBSTRATE

(71) Applicant: Lumentum Operations LLC, San Jose, CA (US)

(72) Inventors: Li FAN, San Jose, CA (US); Victor ROSSIN, Mountain View, CA (US)

(21) Appl. No.: 18/671,459

(22) Filed: May 22, 2024

Related U.S. Application Data
(60) Provisional application No. 63/506,731, filed on Jun. 7, 2023.

(51) Int. Cl. H01S 5/10; H01S 5/20; H01S 5/24

(52) U.S. Cl. CPC H01S 5/1082; H01S 5/2036; H01S 5/24; H01S 2302/00

(57) ABSTRACT

A semiconductor laser may include an off-cut substrate having a cut angle of at least approximately 6 degrees (°). The semiconductor laser may include an epitaxial structure over the off-cut substrate. A first sidewall formed by the off-cut substrate and the epitaxial structure may be parallel to a second sidewall formed by the off-cut substrate and the epitaxial structure. A front facet formed by the off-cut substrate and the epitaxial structure may be parallel to a back facet formed by the off-cut substrate and the epitaxial structure. The cut angle of the off-cut substrate may cause the first sidewall to be non-perpendicular to epitaxial layers of the epitaxial structure. The cut angle of the off-cut substrate may cause the second sidewall to be non-perpendicular to the epitaxial layers of the epitaxial structure.

### CROSS-REFERENCE TO RELATED APPLICATION

This Patent Application claims priority to U.S. Provisional Patent Application No. 63/506,731, filed on Jun. 7, 2023, and entitled “KINK-FREE HIGH FILL-FACTOR BROAD AREA SEMICONDUCTOR LASER ON AN OFF-CUT SUBSTRATE.” The disclosure of the prior Application is considered part of and is incorporated by reference into this Patent Application.

### TECHNICAL FIELD

The present disclosure relates generally to a semiconductor laser and to high fill-factor broad area semiconductor laser on an off-cut substrate.

### BACKGROUND

A broad area laser diode is an edge-emitting laser diode, where an emitting region of a front facet of the broad area laser diode has a shape of a broad stripe or ridge. A fill factor of the broad area laser diode is defined as a percentage (or ratio) of a width of the emitting region compared to a width of the broad area laser diode.

### SUMMARY

In some implementations, a semiconductor laser includes an off-cut substrate having a cut angle of at least approximately 6 degrees (°); and an epitaxial structure over the off-cut substrate; wherein a first sidewall formed by the off-cut substrate and the epitaxial structure is parallel to a second sidewall formed by the off-cut substrate and the epitaxial structure, wherein a front facet formed by the off-cut substrate and the epitaxial structure is parallel to a back facet formed by the off-cut substrate and the epitaxial structure, wherein the cut angle of the off-cut substrate causes the first sidewall to be non-perpendicular to epitaxial layers of the epitaxial structure, and wherein the cut angle of the off-cut substrate causes the second sidewall to be non-perpendicular to the epitaxial layers of the epitaxial structure.

In some implementations, an optical device includes an off-cut substrate having a cut angle of at least approximately 6°; and an epitaxial structure over the off-cut substrate; wherein a first sidewall of the optical device is parallel to a second sidewall of the optical device, wherein a front facet of the optical device is parallel to a back facet of the optical device, wherein the front facet and the back facet are perpendicular to epitaxial layers of the epitaxial structure, and wherein the first sidewall and the second sidewall are non-perpendicular to the epitaxial layers of the epitaxial structure.

In some implementations, a laser device includes a substrate having a cut angle that is greater than or equal to approximately 6°; and an epitaxial structure over the off-cut substrate, the epitaxial structure comprising a plurality of epitaxial layers; wherein sidewalls of the laser device are parallel to each other, wherein the sidewalls are non-perpendicular to the plurality of epitaxial layers, wherein facets of the laser device are parallel to each other, and wherein the facets of the laser device are perpendicular to the plurality of epitaxial layers.

### BRIEF DESCRIPTION OF THE DRAWINGS

FIGS. 1A-1B are diagrams of example implementations described herein.

FIGS. 2A-2B are diagrams of examples of light-current (L-I) curves associated with optical devices.

FIG. 3 is a diagram illustrating one example implementation in which kink-free L-I performance is achieved for an optical device described herein.

### DETAILED DESCRIPTION

The following detailed description of example implementations refers to the accompanying drawings. The same reference numbers in different drawings may identify the same or similar elements.

To achieve a high power output (e.g., a high optical power output) of a laser device (e.g., a broad area laser device) and to reduce a size of the laser device and/or a cost associated with manufacturing the laser device, a high fill factor of the laser device is preferred. For example, a fill factor that is greater than or equal to 60% is often preferred. However, in many cases, such a high fill factor enables formation of non-preferred in-epitaxial-plane (in-epi-plane) lasing within the laser device. That is, a high fill factor often enables formation of ring modes and/or other non-preferred in-epi-plane lasing modes within an epitaxial structure of the laser device.

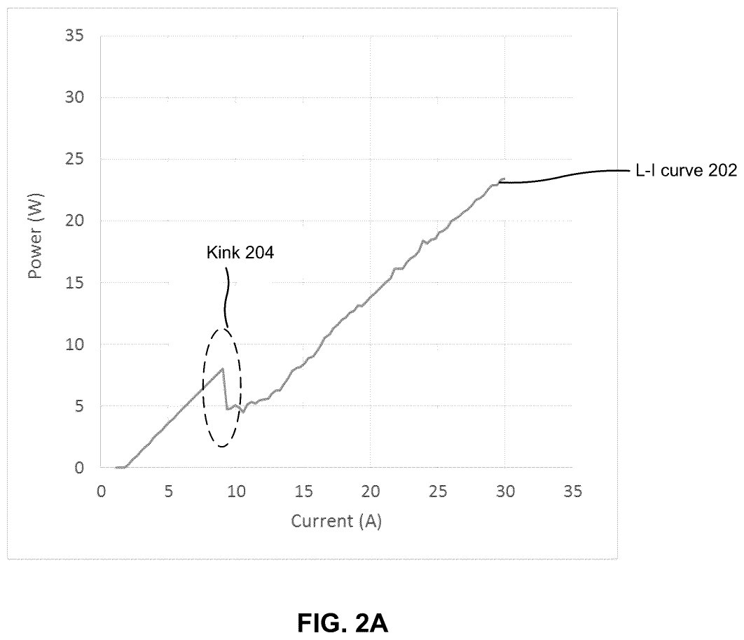

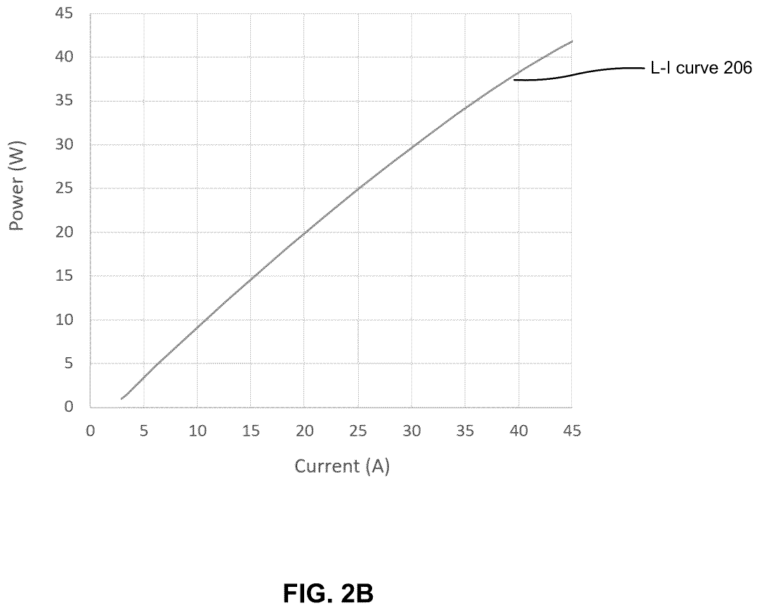

For example, a near-infrared (NIR) diode laser device may comprise an epitaxial structure that is grown on a gallium arsenide (GaAs) substrate having a crystal orientation of (001), meaning that a shape of a single emitter facet is a rectangle. In a lateral direction, both side facets of the laser device are perpendicular to the epi-plane and form a Fabry-Perot (FP) resonator, which supports lateral lasing. Further, a high fill factor may result in a formation of a ring resonator in an epi-plane by a front facet, a back facet, and side facets of the laser device, which supports ring lasing in the epi-plane (e.g., at high current pumping). In an un-pumped passive area, a quantum well (QW) temperature is substantially lower than that in a pumped area. Thus, the un-pumped passive area may be transparent to a laser signal (e.g., because lower temperature results in higher bandgap energy). The reflection of the ring laser signal on a side of the laser device is total internal reflection, which is lossless to the ring laser signal. For a single emitter with a fill fact over 60% and a long cavity, ring laser modes have enough gain to balance mirror loss and other losses, and therefore the ring laser modes have a chance to lase. Notably, lateral lasing has a lower chance to lase since lateral lasing mirror loss is likely to be at least ten times higher than a designed FP resonator ridge cavity of the laser device. However, the lateral FP resonator and the in-plane ring resonator enhance QW spontaneous emission, which results in loss to the laser device. These in-epi-plane lasers will compete with a designed ridge waveguide laser. As a result, power performance (e.g., an optical power performance) of the laser device will not be consistent or predictable (e.g., when a current applied to the laser device changes). This is indicated by a light-current (L-I) curve associated with the laser device, which often has a kink and is not smooth (e.g., as described herein in relation to FIG. 2A). Consequently, the laser device cannot be used in applications where a more consistent and predictable power performance is desired.

Some implementations described herein provide an optical device (e.g., a laser device, such as a broad area semiconductor laser) that includes an off-cut substrate and an epitaxial structure over the off-cut substrate. In some implementations, the off-cut substrate may have a cut angle of at least approximately 6°. In some implementations, the cut angle of the off-cut substrate causes a first sidewall of the optical device to be non-perpendicular to epitaxial layers of the epitaxial structure and, similarly, causes a second sidewall of the optical device to be non-perpendicular to the epitaxial layers of the epitaxial structure.

In some implementations, the cut angle prevents total internal reflection on an interface of a waveguide and a cladding, meaning that a lateral cavity and a ring cavity do not exist within the optical device. As a result, unwanted lateral lasing and ring lasing within the epitaxial structure is eliminated, thereby improving power performance of the optical device. Thus, even when the optical device has a high fill factor (e.g., a fill factor that is greater than or equal to 60%), a power performance of the optical device (e.g., when changing the current of the optical device) is more consistent and predictable than that of the laser device described above. This is indicated by an L-I curve associated with the optical device, which does not have a kink (e.g., is “kink-free”) and is smooth (e.g., as described herein in relation to FIG. 2B). Further, the power performance of the optical device is more efficient because applying an increased current to the optical device reliably results in an increased power of the optical device. Accordingly, the optical device can be used in applications where a more consistent and predictable power performance is required (and in which the laser device described above cannot be used). Additional details are provided below.

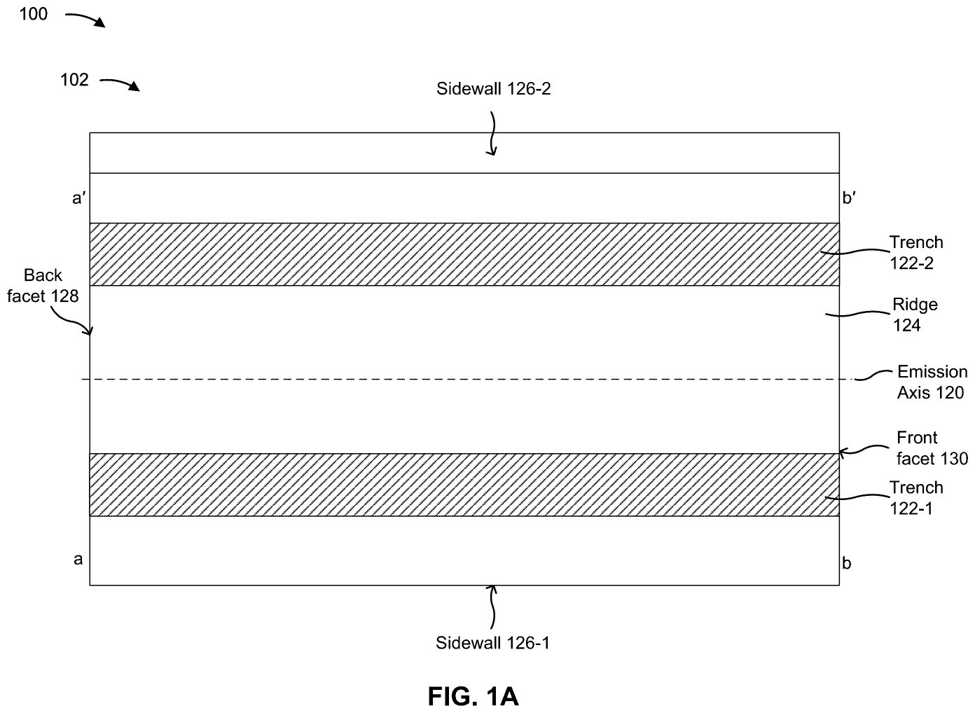

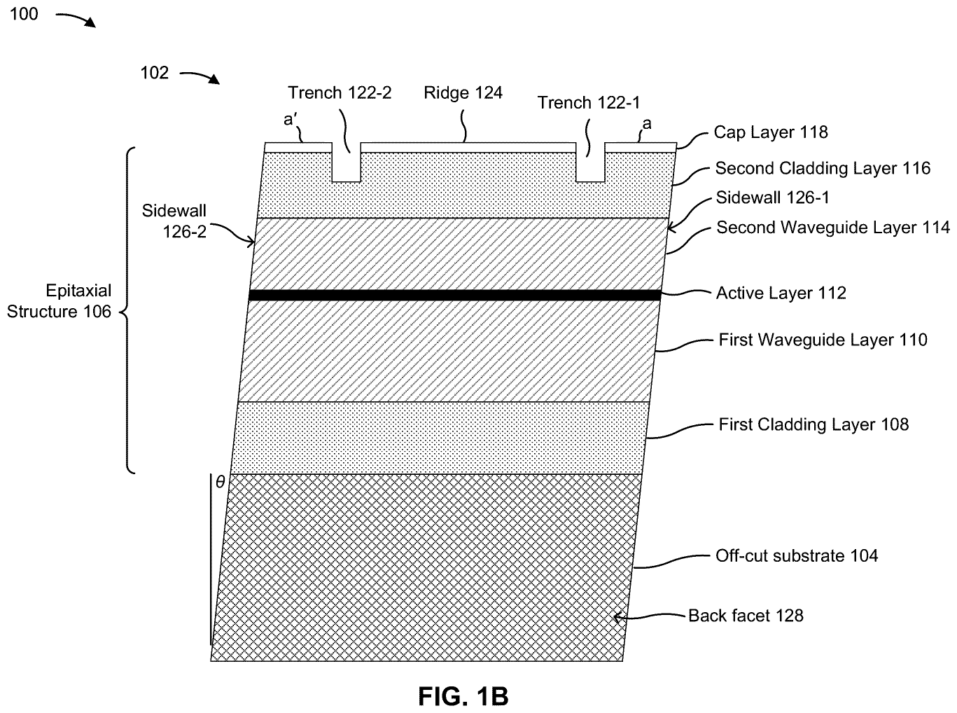

FIGS. 1A-1B are diagrams of example implementations 100 described herein. As shown in FIGS. 1A-1B, each example implementation 100 may include an optical device 102. FIG. 1A shows a top-down view of the optical device 102, while FIG. 1B shows a back-end view of the optical device 102 (e.g., a view of a back facet 128, from the left side of the optical device 102 as shown in FIG. 1A). Notably, a front-end view of the optical device 102 (e.g., a view of a front facet 130, from the right side of the optical device 102 as shown in FIG. 1A) may be similar to the back-end view illustrated in FIG. 1B.

As shown in FIG. 1B, the optical device 102 may include an off-cut substrate 104 and an epitaxial structure 106 that is disposed over (e.g., directly on, or indirectly on) the off-cut substrate 104 (e.g., a top surface of the off-cut substrate 104). The epitaxial structure 106 may comprise a first cladding layer 108 (e.g., disposed over the off-cut substrate 104), a first waveguide layer 110 (e.g., disposed over the first cladding layer 108), an active layer 112 (e.g., disposed over the first waveguide layer 110), a second waveguide layer 114 (e.g., disposed over the active layer 112), a second cladding layer 116 (e.g., disposed over the second waveguide layer 114), and/or a cap layer 118 (e.g., disposed over the second cladding layer 116). The layers of the epitaxial structure 106 are also off-cut the same as the off-cut substrate 104, thereby forming a parallelogram or angled cross-section, as shown in FIG. 1B. As further illustrated in FIG. 1A, a portion of the sidewall 126-2 would be visible from the top view of the optical device 102 due to the off-cut angle θ of the optical device 102.

The optical device 102 may be a laser device or another type of light-emitting device. For example, the optical device 102 may be a broad area semiconductor laser configured to emit a laser beam, such as a near-infrared (NIR) laser beam (e.g., a beam having a wavelength within a range from approximately 700 nanometers (nm) to approximately 1600 nm). The optical device 102 may be configured to generate, propagate, and emit the laser beam along an emission axis 120 (e.g., between the back end of the optical device 102 and the front end of the optical device 102, or vice versa).

In some implementations, the off-cut substrate 104 may be a gallium arsenide (GaAs) substrate (e.g., a GaAs substrate having a crystal axis orientation of (001)). Alternatively, the off-cut substrate 104 may in some implementations be an indium phosphide (InP) substrate, or another type of substrate (e.g., with a Bravais lattice structure). Additionally, or alternatively, the off-cut substrate 104 may be doped. For example, the off-cut substrate 104 may be an n-doped substrate. The off-cut substrate 104 may be formed from a wafer (e.g., a slice) from a boule, and various other layers of the epitaxial structure 106 may be formed (e.g., grown) over the off-cut substrate 104 (e.g., over a top surface of the off-cut substrate 104 as shown in FIG. 1B) prior to cutting the substrate at the off-cut angle θ. Additional details regarding the off-cut substrate 104 are provided below.

The first cladding layer 108 may be capable of confining (e.g. vertically) light (e.g., of a laser beam) within the first waveguide layer 110, the active layer 112, and/or the second waveguide layer 114. In some implementations, the first cladding layer 108 may be doped. For example, the first cladding layer 108 may be an n-doped cladding layer. The first waveguide layer 110 may be capable of guiding light (e.g., of a laser beam) in a particular direction within the optical device 102 (e.g., along the emission axis 120 of the optical device 102), and/or confining (e.g. vertically) the light within the active layer 112. The active layer 112 may be capable of acting as an active region of the optical device 102 (e.g., acting as a laser active region within a laser cavity when the epitaxial structure 106 is included in a laser device). The active layer 112 may include one or more QWs. The second waveguide layer 114 may be capable of guiding light (e.g., of a laser beam) in the particular direction within the optical device 102 (e.g., along the emission axis 120 of the optical device 102), and/or confining (e.g. vertically) the light within the active layer 112. The second cladding layer 116 may be capable of confining (e.g. vertically) light (e.g., of a laser beam) within the first waveguide layer 110, the active layer 112, and/or the second waveguide layer 114. In some implementations, the second cladding layer 116 may be doped. For example, the second cladding layer 116 may be a p-doped cladding layer. The cap layer 118 may be capable of protecting other layers of the epitaxial structure 106 (e.g., when the cap layer 118 is formed as a top layer of the epitaxial structure 106). In some implementations, the cap layer 118 may be highly doped. For example, the cap layer 118 may be a highly doped p-doped cap layer.

In some implementations, the off-cut substrate 104 is formed such that a sidewall of the off-cut substrate 104 is non-perpendicular to a surface of the off-cut substrate 104. For example, as indicated in FIG. 1B, the off-cut substrate 104 may be formed with a cut angle θ that causes the sidewall of the off-cut substrate 104 to be non-perpendicular to a bottom surface of the off-cut substrate 104. In so forming the sidewall of the off-cut substrate 104, the sidewall of the epitaxial structure 106 is also formed to be non-perpendicular to a surface (e.g. bottom or lateral surface) of the epitaxial structure 106. In some implementations, the cut angle θ may be at least approximately 6°, which may substantially reduce lateral internal reflection of the sidewalls 126. In some implementations, the cut angle may be less than approximately 15°, which may maintain quality of the epitaxial layers and yield. In some implementations, the cut angle θ may be selected based on a refractive index contrast between a waveguide layer of the epitaxial structure 106 and a cladding layer of the epitaxial structure 106. For example, to eliminate lateral lasing and ring lasing, a minimum cut angle θ of the off-cut substrate 104 may be determined based on a refractive index contrast between the first waveguide layer 110 and the first cladding layer 108 (or by a refractive index contrast between the second waveguide layer 114 and the second cladding layer 116). As a particular example, for a vertical fundamental mode reflected by an angled sidewall, the minimum cut angle θ can be determined as a value equal to (90°−sin⁻¹(n₂/n₁))/2, where n₁ is a refractive index of the first waveguide layer 110 and n₂ is a refractive index of the first cladding layer 108.

In some implementations, as illustrated in FIG. 1B, a first sidewall 126-1 formed by the off-cut substrate 104 and the epitaxial structure 106 is parallel to a second sidewall 126-2 formed by the off-cut substrate 104 and the epitaxial structure 106. That is, the sidewalls 126 of the optical device 102 may in some implementations be parallel to one another. Further, the cut angle θ of the off-cut substrate 104 causes a sidewall 126 to be non-perpendicular to epitaxial layers of the epitaxial structure 106. For example, the cut angle θ of the off-cut substrate 104 causes the first sidewall 126-1 to be non-perpendicular to epitaxial layers of the epitaxial structure 106 (e.g., the first cladding layer 108, the first waveguide layer 110, the active layer 112, the second waveguide layer 114, the second cladding layer 116, and the cap layer 118). Similarly, the cut angle θ of the off-cut substrate 104 causes the second sidewall 126-2 to be non-perpendicular to the epitaxial layers of the epitaxial structure 106 (e.g., the first cladding layer 108, the first waveguide layer 110, the active layer 112, the second waveguide layer 114, the second cladding layer 116, and the cap layer 118).

In some implementations, as illustrated in FIG. 1A, the front facet 130 formed by the off-cut substrate 104 and the epitaxial structure 106 is parallel to the back facet 128 formed by the off-cut substrate 104 and the epitaxial structure 106. That is, facets of the optical device 102 may in some implementations be parallel to one another. Further, as can be understood from FIGS. 1A and 1B, the front facet 130 and/or the back facet 128 may in some implementations be perpendicular to epitaxial layers within the epitaxial structure 106. For example, the front facet 130 and the back facet 128 of the optical device 102 may in some implementations be perpendicular to the first cladding layer 108, the first waveguide layer 110, the active layer 112, the second waveguide layer 114, the second cladding layer 116, or the cap layer 118. In some implementations, as further illustrated in FIG. 1B, the front facet 130 of the optical device 102 and/or the back facet 128 of the optical device 102 may have a parallelogram shape.

As noted above, the off-cut substrate 104 with the cut angle θ provides an emitter with parallelogram shaped facets that are perpendicular to epitaxial layers in the epitaxial structure 106 in the emission direction into and out of a plane of the page in FIG. 1A, which forms an FP cavity. Further, the sidewalls 126 along the laser cavity are non-perpendicular to the epitaxial layers of the epitaxial structure 106 (and may be parallel to one another), meaning that a lateral FP resonator is not formed in the epi-plane. Here, if the first waveguide layer 110 has a higher refractive index than the first cladding layer 108 and the second waveguide layer 114 has a higher refractive index than the second cladding layer 116, and the cut angle θ is sufficient such that there is no total internal reflection on a waveguide/cladding interface, then no lateral cavity and ring cavity is formed, meaning that lateral lasing and ring lasing are eliminated in the optical device 102.

In some implementations, the optical device 102 may include a pair of trenches 122 associated with controlling horizontal far field divergence. These trenches 122 are optional. For example, as shown in FIGS. 1A-1B, the optical device 102 may include a pair of trenches 122 (shown as trenches 122-1 and 122-2). As shown in FIG. 1A, the pair of trenches 122 may be formed in a surface (e.g., a top surface) of the optical device 102. That is, as shown in FIG. 1B, the pair of trenches 122 may be formed in a surface (e.g., a top surface) of the epitaxial structure 106 that comprises the surface of the optical device 102.

As shown in FIG. 1A, the pair of trenches 122 may be formed in an inner region (e.g., a central region) of the surface of the optical device 102 (e.g., an inner region of the surface of the epitaxial structure 106). The pair of trenches 122 may be formed along a dimension of the inner region of the surface of the optical device 102 (e.g., along a dimension of the inner region of the surface of the epitaxial structure 106) that is substantially parallel to (e.g., within a tolerance, which may be less than or equal to 1 degree, 2 degrees, and/or 3 degrees, among other examples) to the emission axis 120. For example, as shown in FIG. 1A, the pair of trenches 122 may be formed along a length (e.g., shown as a horizontal dimension) of the inner region of the surface of the optical device 102.

In some implementations, the pair of trenches 122 may define the ridge 124 of the optical device 102 (e.g., the ridge 124 of the epitaxial structure 106). For example, as shown in FIGS. 1A-1B, the ridge 124 may be an area of the inner region of the surface of the optical device 102 that is bounded by the pair of trenches 122. In some implementations, a width of the ridge 124 may be defined as a distance between inner-facing edges of the pair of trenches 122. A fill factor of the optical device 102 may be defined as a percentage (or ratio) of the width of the ridge 124 as compared to a width of the optical device 102. In some implementations, the fill factor of the optical device 102 may be at least 60%, such as 61%, 62.5%, 65%, or 67.5%. That is, in some implementations, a width of the ridge 124 of the optical device 102 is at least approximately 60% of a width of the optical device 102. In a prior optical device with sidewalls perpendicular to the epitaxial layers and a fill factor of at least 60%, the corresponding L-I performance (see FIG. 2A) exhibits power loss to unwanted lasing modes (e.g. lateral and ring lasing) in operation. In embodiments of the present invention, with or without a fill factor of at least 60%, the angled sidewalls 126 of the epitaxial structure 106 prevent this power loss (sec FIG. 2B).

In some implementations, the pair of trenches 122 may be formed using an etching technique (e.g., using a wet etching technique or a dry etching technique). In some implementations, each trench 122, of the pair of trenches 122, may extend into at least the second cladding layer 116. For example, as shown in FIG. 1B, each trench 122 may extend through the cap layer 118 into the second cladding layer 116. In some implementations, each trench 122 does not extend into the second waveguide layer 114 and/or does not extend into the active layer 112. In some implementations, each trench 122 may have sidewalls that are substantially parallel (e.g., within a tolerance, which may be less than or equal to 1 degree, 2 degrees, and/or 3 degrees, among other examples) to an epitaxial formation axis of the optical device 102 (e.g., a vertical direction, as shown in FIG. 1B), such as due to a dry etching technique. Accordingly, each trench 122 may have “vertical” sidewalls, such as shown in FIG. 1B. Alternatively, each trench 122 may have sidewalls that are at a non-zero angle to the epitaxial formation axis, such as due to using a wet etching technique. Accordingly, each trench 122 may in some implementations have “non-vertical” sidewalls.

In some implementations, the pair of trenches 122 may be formed to have a particular depth and/or width, such that the pair of trenches 122 are configured to cause a slow axis far field divergence angle associated with the optical device 102 to satisfy a divergence angle threshold. That is, the pair of trenches 122 may be configured to cause the slow axis far field divergence angle associated with the optical device 102 to be less than or equal to the divergence angle threshold, which may be less than or equal to 7 degrees, 10 degrees, or 15 degrees, among other examples. For example, the depth and/or width of the pair of trenches 122 may define an effective refractive index contrast of the second waveguide layer 114 (e.g., in the slow axis direction). In this way, the pair of trenches 122 may be formed to prevent the slow axis far field divergence angle associated with the optical device 102 from exceeding the divergence angle threshold.

In some implementations, the use of the off-cut substrate 104 and the pair of trenches 122 enables a broad area single emitter that achieves both kink-free L-I performance and an acceptable slow axis divergence angle. In some implementations, the use of the off-cut substrate 104 simplifies the wafer process while reducing a cost of the optical device 102.

As indicated above, FIGS. 1A-1B are provided merely as examples. Other examples may differ from what is described with regard to FIGS. 1A-1B.

FIGS. 2A-2B are diagrams of examples of light-current (L-I) curves associated with optical devices.

FIG. 2A shows an L-I curve 202 associated with an optical device that does not include the off-cut substrate 104 (e.g., does not include angled sidewalls) or the pair of trenches 122 described herein. The optical device may, for example, have a width of 400 micrometers (μm) and a length of 4.8 mm, and a ridge of the optical device may have a width of 250 μm and a length of 4.8 mm. Accordingly, the optical device may have a fill factor of 62.5% (e.g., 250 μm divided by 400 μm). As shown in FIG. 2A, the L-I curve 202 includes a kink 204, where a power (an optical power, in Watts (W)) of the optical device decreases as a current (in Amps (A)) applied to the optical device increases (e.g., when the current applied to the optical device increases from approximately 9 A to 10 A). As further shown, the L-I curve 202 is not smooth, such that an incremental change in the current may result in more than, or less than, an incremental change in the power of the optical device. Consequently, a power performance of the optical device (e.g., when changing the current that is applied to the optical device) is not consistent or predictable. Further, in some cases, applying an increased current results in a reduced power of the optical device.

FIG. 2B shows an L-I curve 206 associated with an example configuration of the optical device 102, which includes the off-cut substrate 104 (e.g., includes the angled sidewalls) and the pair of trenches 122 described herein. The optical device 102 may, for example, have a width of 400 μm and a length of 5.5 mm, and the ridge 124 of the optical device 102 may have a width of 270 μm and a length of 5.5 mm. Accordingly, the example configuration of the optical device 102 may have a fill factor of 67.5% (e.g., 270 μm divided by 400 μm). As shown in FIG. 2B, the L-I curve 206 does not include a kink. Further, the L-I curve 206 is smooth, such that an incremental change in current applied to the optical device 102 results in an incremental change in a power of the optical device. Accordingly, a power performance of the optical device 102 (e.g., when changing the current of the optical device) is more consistent and predictable than that of the optical device described herein in relation to FIG. 2A. Further, the power performance of the optical device 102 is more efficient because applying an increased current to the optical device 102 results in an increased power of the optical device 102.

As indicated by the L-I curve 206, the optical device 102 provides an improved power performance as compared to that of the optical device described herein in relation to FIG. 2A. This is because the optical device 102 includes the off-cut substrate 104 that causes angled sidewalls 126 in the epitaxial structure 106 which minimizes, or prevents, formation of ring modes and/or other non-preferred in-epi-plane lasing modes within the epitaxial structure 106 of the optical device 102 (e.g., as described herein). In this way, current applied to the optical device 102 is used to form a preferred lasing mode of the optical device 102. Accordingly, in many cases, the optical device 102 provides a higher power per amp than a similar optical device that does not include the off-cut substrate 104.

As indicated above, FIGS. 2A-2B are provided merely as examples. Other examples may differ from what is described with regard to FIGS. 2A-2B.

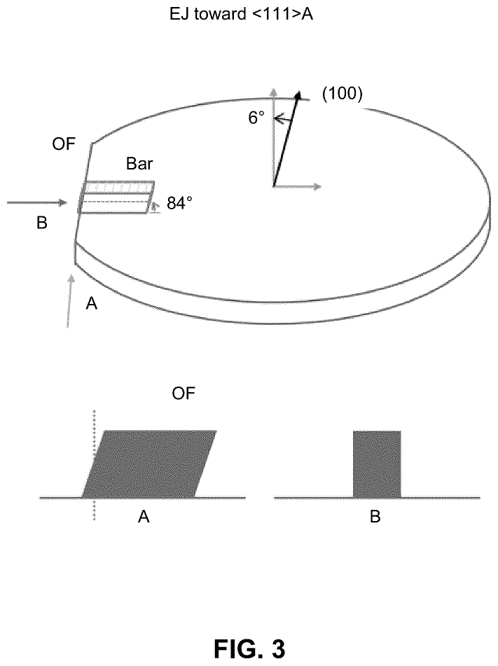

FIG. 3 is a diagram illustrating one example implementation in which kink-free L-I performance is achieved for an optical device 102.

In the example shown in FIG. 3, a 6° off-cut GaAs substrate is used for growth of the epitaxial structure (e.g., the epitaxial structure 106). An optical axis is into/out of a plane of the page of FIG. 3 or is along the dark black axis of the wafer. In the example shown in FIG. 3, the substrate uses a Europe-Japan (EJ) flat option, “OF” refers to orientation flat (major flat), and “<111>A” refers to a crystal orientation. In this example, after bar cleaving, cleaved facets have different shapes when the resulting bar is viewed from direction A and direction B indicated in FIG. 3. As illustrated in FIG. 3, and as noted above, the front and back facets are parallel to one another and are perpendicular to epitaxial layers within the epitaxial structure.

As indicated above, FIG. 3 is provided as an example. Other examples may differ from what is described with regard to FIG. 3.

The foregoing disclosure provides illustration and description, but is not intended to be exhaustive or to limit the implementations to the precise forms disclosed. Modifications and variations may be made in light of the above disclosure or may be acquired from practice of the implementations. Furthermore, any of the implementations described herein may be combined unless the foregoing disclosure expressly provides a reason that one or more implementations may not be combined.

Even though particular combinations of features are recited in the claims and/or disclosed in the specification, these combinations are not intended to limit the disclosure of various implementations. In fact, many of these features may be combined in ways not specifically recited in the claims and/or disclosed in the specification. Although each dependent claim listed below may directly depend on only one claim, the disclosure of various implementations includes each dependent claim in combination with every other claim in the claim set. As used herein, a phrase referring to “at least one of” a list of items refers to any combination of those items, including single members. As an example, “at least one of: a, b, or c” is intended to cover a, b, c, a-b, a-c, b-c, and a-b-c, as well as any combination with multiple of the same item.

When a component or one or more components (e.g., a laser emitter or one or more laser emitters) is described or claimed (within a single claim or across multiple claims) as performing multiple operations or being configured to perform multiple operations, this language is intended to broadly cover a variety of architectures and environments. For example, unless explicitly claimed otherwise (e.g., via the use of “first component” and “second component” or other language that differentiates components in the claims), this language is intended to cover a single component performing or being configured to perform all of the operations, a group of components collectively performing or being configured to perform all of the operations, a first component performing or being configured to perform a first operation and a second component performing or being configured to perform a second operation, or any combination of components performing or being configured to perform the operations. For example, when a claim has the form “one or more components configured to: perform X; perform Y; and perform Z,” that claim should be interpreted to mean “one or more components configured to perform X; one or more (possibly different) components configured to perform Y; and one or more (also possibly different) components configured to perform Z.”

No element, act, or instruction used herein should be construed as critical or essential unless explicitly described as such. Also, as used herein, the articles “a” and “an” are intended to include one or more items, and may be used interchangeably with “one or more.” Further, as used herein, the article “the” is intended to include one or more items referenced in connection with the article “the” and may be used interchangeably with “the one or more.” Furthermore, as used herein, the term “set” is intended to include one or more items (e.g., related items, unrelated items, or a combination of related and unrelated items), and may be used interchangeably with “one or more.” Where only one item is intended, the phrase “only one” or similar language is used. Also, as used herein, the terms “has,” “have,” “having,” or the like are intended to be open-ended terms. Further, the phrase “based on” is intended to mean “based, at least in part, on” unless explicitly stated otherwise. Also, as used herein, the term “or” is intended to be inclusive when used in a series and may be used interchangeably with “and/or,” unless explicitly stated otherwise (e.g., if used in combination with “either” or “only one of”). Further, spatially relative terms, such as “below,” “lower,” “above,” “upper,” and the like, may be used herein for ease of description to describe one element or feature's relationship to another element(s) or feature(s) as illustrated in the figures. The spatially relative terms are intended to encompass different orientations of the apparatus, device, and/or element in use or operation in addition to the orientation depicted in the figures. The apparatus may be otherwise oriented (rotated 90 degrees or at other orientations) and the spatially relative descriptors used herein may likewise be interpreted accordingly.

What is claimed is:

1. A semiconductor laser, comprising:
an off-cut substrate having a cut angle of at least approximately 6 degrees) (°; and
an epitaxial structure over the off-cut substrate;
wherein a first sidewall formed by the off-cut substrate and the epitaxial structure is parallel to a second sidewall formed by the off-cut substrate and the epitaxial structure,
wherein a front facet formed by the off-cut substrate and the epitaxial structure is parallel to a back facet formed by the off-cut substrate and the epitaxial structure,
wherein the cut angle of the off-cut substrate causes the first sidewall to be non-perpendicular to epitaxial layers of the epitaxial structure, and
wherein the cut angle of the off-cut substrate causes the second sidewall to be non-perpendicular to the epitaxial layers of the epitaxial structure.

2. The semiconductor laser of claim 1, wherein the cut angle is less than approximately 15°.

3. The semiconductor laser of claim 1, wherein the cut angle is based on a refractive index contrast between a waveguide layer of the epitaxial structure and a cladding layer of the epitaxial structure.

4. The semiconductor laser of claim 1, wherein at least one of the front facet or the back facet has a parallelogram shape.

5. The semiconductor laser of claim 1, wherein at least one of the front facet or the back facet is perpendicular to the epitaxial layers within the epitaxial structure.

6. The semiconductor laser of claim 1, wherein the semiconductor laser has a fill factor of at least approximately 60%.

7. The semiconductor laser of claim 1, wherein the semiconductor laser is a broad area laser device that is to emit a near-infrared (NIR) beam.

8. The semiconductor laser of claim 1, wherein the epitaxial structure comprises a set of trenches formed in a surface of the epitaxial structure.

9. An optical device, comprising:
an off-cut substrate having a cut angle of at least approximately 6 degrees (°); and
an epitaxial structure over the off-cut substrate;
wherein a first sidewall of the optical device is parallel to a second sidewall of the optical device,
wherein a front facet of the optical device is parallel to a back facet of the optical device,
wherein the front facet and the back facet are perpendicular to epitaxial layers of the epitaxial structure, and
wherein the first sidewall and the second sidewall are non-perpendicular to the epitaxial layers of the epitaxial structure.

10. The optical device of claim 9, wherein the cut angle is less than approximately 15°.

11. The optical device of claim 9, wherein the cut angle is based on a refractive index contrast between a waveguide layer of the epitaxial structure and a cladding layer of the epitaxial structure.

12. The optical device of claim 9, wherein the front facet and the back facet have a parallelogram shape.

13. The optical device of claim 9, wherein a width of a ridge of the optical device is at least at least approximately 60% of a width of the optical device.

14. The optical device of claim 9, wherein the optical device is a broad area laser device that is to emit a near-infrared (NIR) beam.

15. The optical device of claim 9, wherein the epitaxial structure comprises a set of trenches formed in a surface of the epitaxial structure.

16. A laser device, comprising:
a substrate having a cut angle that is greater than or equal to approximately 6 degrees (°); and
an epitaxial structure over the substrate, the epitaxial structure comprising a plurality of epitaxial layers;
wherein sidewalls of the laser device are parallel to each other,
wherein the sidewalls are non-perpendicular to the plurality of epitaxial layers,
wherein facets of the laser device are parallel to each other, and
wherein the facets of the laser device are perpendicular to the plurality of epitaxial layers.

17. The laser device of claim 16, wherein the cut angle is less than approximately 15°.

18. The laser device of claim 16, wherein the cut angle is selected based on a refractive index contrast between a waveguide layer of the epitaxial structure and a cladding layer of the epitaxial structure.

19. The laser device of claim 16, wherein the facets have a parallelogram shape.

20. The laser device of claim 16, wherein the laser device has a fill factor of at least approximately 60%.
